(19) United States
(12) Patent Application Publication
(10) Pub. No.: US 2024/0363390 A1
(43) Pub. Date: Oct. 31, 2024

(54) GAS FLOW SUBSTRATE SUPPORTS, PROCESSING CHAMBERS, AND RELATED METHODS AND APPARATUS, FOR SEMICONDUCTOR MANUFACTURING

(71) Applicant: Applied Materials, Inc., Santa Clara, CA (US)

(72) Inventors: Xinning LUAN, Tempe, AZ (US); Shawn THOMAS, Chesterfield, MO (US); Hui CHEN, Tempe, AZ (US)

(21) Appl. No.: 18/540,680

(22) Filed: Dec. 14, 2023

Related U.S. Application Data
(60) Provisional application No. 63/462,129, filed on Apr. 26, 2023.

(51) Int. Cl. H01L 21/687; C23C 16/458; C30B 25/10; C30B 25/12

(52) U.S. Cl. CPC H01L 21/68735; C23C 16/4586; C30B 25/10; C30B 25/12; H01L 21/68742

(57) ABSTRACT

The present disclosure relates to gas flow substrate supports, processing chambers, and related methods and apparatus, for semiconductor manufacturing. In one or more embodiments, a substrate support applicable for semiconductor manufacturing includes a first outer surface, a ledge disposed inwardly of the first outer surface and recessed relative to the first outer surface, and a pocket defining a pocket surface that is disposed inwardly of the ledge and recessed relative to the ledge. The substrate support includes a plurality of first flow openings extending into the pocket surface, a plurality of second flow openings extending into the ledge, and a plurality of third flow openings extending into the first outer surface.

### CROSS-REFERENCE TO RELATED APPLICATION

This application claims priority to United States Provisional Patent Application No. 63/462,129, filed Apr. 26, 2023, which is herein incorporated by reference in its entirety.

### BACKGROUND

### Field

The present disclosure relates to gas flow substrate supports, processing chambers, and related methods and apparatus, for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, substrate supports can cause unwanted deposition and/or unwanted contamination. For example, metal contaminants can contaminate a substrate and/or can wear a coating on a substrate support. As another example, film can be deposited on certain areas of components, such as on the substrate support and/or on a backside of a substrate. Film and/or contaminants can also gather to fuse the substrate to the substrate support, which can cause substrate breakage.

Therefore, a need exists for improved apparatuses and methods in semiconductor processing.

### SUMMARY

The present disclosure relates to gas flow substrate supports, processing chambers, and related methods and apparatus, for semiconductor manufacturing.

In one or more embodiments, a substrate support applicable for semiconductor manufacturing includes a first outer surface, a ledge disposed inwardly of the first outer surface and recessed relative to the first outer surface, and a pocket defining a pocket surface that is disposed inwardly of the ledge and recessed relative to the ledge. The substrate support includes a plurality of first flow openings extending into the pocket surface, a plurality of second flow openings extending into the ledge, and a plurality of third flow openings extending into the first outer surface.

In one or more embodiments, a substrate support applicable for semiconductor manufacturing includes a first outer surface, and a pocket defining a pocket surface that is disposed inwardly of the first outer surface and recessed relative to the first outer surface. The substrate support includes one or more lift pin openings. At least one of the one or more lift pin openings includes an opening section having a diameter, and a ledge recessed relative to the pocket surface by a first distance and extending by a second distance. A sum of the first distance and the second distance lesser than the diameter. The at least one of the one or more lift pin openings includes a hole section extending relative to the ledge.

In one or more embodiments, a processing chamber applicable for semiconductor manufacturing includes one or more sidewalls, a window at least partially defining a processing volume, one or more heat sources operable to heat the processing volume, and a substrate support disposed in the processing volume. The substrate support includes a first outer surface, a ledge disposed inwardly of the first outer surface and recessed relative to the first outer surface, and a pocket defining a pocket surface that is disposed inwardly of the ledge and recessed relative to the ledge. The substrate support includes a plurality of second flow openings extending into the ledge, a plurality of third flow openings extending into the first outer surface, and one or more lift pin openings. At least one of the one or more lift pin openings includes an opening section having a diameter, and a ledge recessed relative to the pocket surface by a first distance and extending by a second distance. A sum of the first distance and the second distance is lesser than the diameter.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic top view of a substrate support, according to one or more embodiments.

FIG. 3 is a schematic side cross-sectional view, along Section 3-3, of the substrate support shown in FIG. 2, according to one or more embodiments.

FIG. 4 is a schematic side cross-sectional view, along Section 4-4, of the substrate support shown in FIG. 2, according to one or more embodiments.

FIG. 5 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to gas flow substrate supports, processing chambers, and related methods and apparatus, for semiconductor manufacturing.

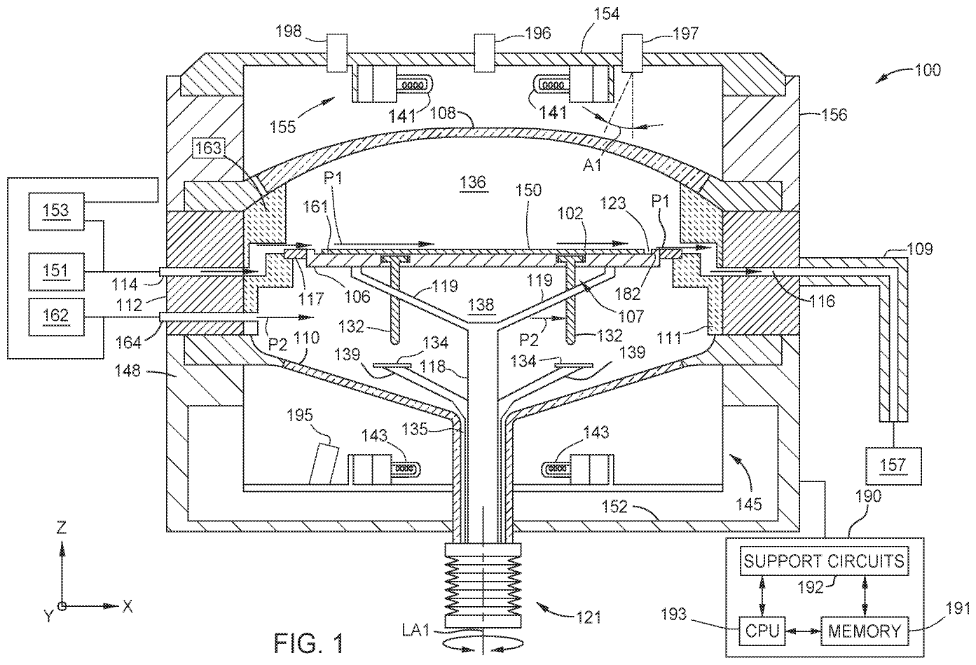

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), and one or more heat sources 141, 143. The one or more heat sources 141, 143 include a plurality of upper heat sources 141 and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155.

The plurality of lower heat sources 143 are disposed between the lower window 110 and a floor 152. The plurality of lower heat sources 143 form a portion of a lower heat source module 145. The upper window 108 is an upper dome and/or is formed of an energy transmissive material, such as quartz. The lower window 110 is a lower dome and/or is formed of an energy transmissive material, such as quartz.

A processing volume 136 and a purge volume 138 are formed between the upper window 108 and the lower window 110. The processing volume 136 and the purge volume 138 are part of an internal volume defined at least partially by the upper window 108, the lower window 110, and one or more liners 111, 163. In one or more embodiments, the processing volume 136 is a processing volume. The one or more liners 111, 163 are disposed inwardly of the chamber body.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin openings 107 disposed therein. The lift pin openings 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The pre-heat ring 117 can include a complete ring or one or more ring segments. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The processing system includes one or more sensor devices 195, 196, 197, 198 (e.g., temperature sensors) configured to measure parameter(s) (e.g., temperature(s)) within the processing chamber 100. In one or more embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensor devices 195, 196, 197, 198. In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods (e.g., the method 500) described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the substrate support 106, and/or the liners 111, 163. As described the one or more sensor devices can include, for example pyrometers.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power applied to the heat sources 141, 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein (such as operation(s) of the method 500) to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the heat sources 141, 143, the deposition, the cleaning, the rotational position, the heating, and gas flow through the processing chamber 100 by providing an output to the controls for the sensor devices 195, 196, 197, 198, the upper heat sources 141, the lower heat sources 143, the process gas source 151, the purge gas source 162, the motion assembly 121, and/or the exhaust pump 157.

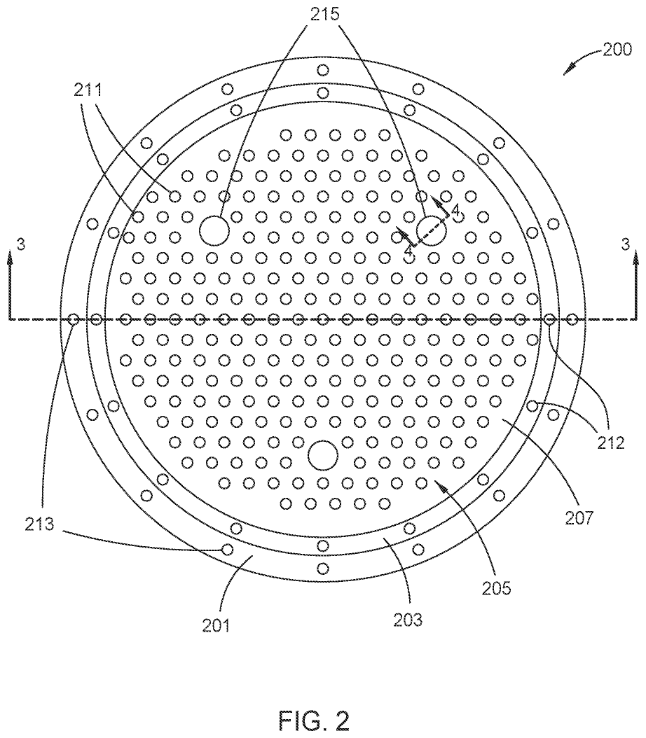

FIG. 2 is a schematic top view of a substrate support 200, according to one or more embodiments. The substrate support 200 can be used as the substrate support 106 shown in FIG. 1.

The substrate support 200 includes a first outer surface 201 and a ledge 203 disposed inwardly of the first outer surface 201 and recessed relative to the first outer surface 201. In one or more embodiments, the first outer surface 201 is an upper surface. The substrate support 200 includes a pocket 205 defining a pocket surface 207 that is disposed inwardly of the ledge 203 and recessed relative to the ledge 203. The substrate support 200 includes a plurality of first flow openings 211 (e.g., first gas openings) extending into the pocket surface 207, a plurality of second flow openings 212 (e.g., second gas openings) extending into the ledge 203, and a plurality of third flow openings 213 (e.g., third gas openings) extending into the first outer surface 201. The substrate support 200 includes a plurality of lift pin openings 215 extending into the pocket surface 207. The second flow openings 212 and the third flow openings 213 are respectively disposed along a circular row. The first flow openings 211 are disposed along a plurality of rows. In one or more embodiments, the rows are diagonal rows. The diagonal rows can be part of hexagonal rings, for example. In one or more embodiments, the rows are circular rows, such as circular rows that are concentric with each other. In one or more embodiments, one of the first flow openings 211 is centrally disposed inwardly of the rows. In one or more embodiments, the second flow openings 212 are disposed radially outwardly of the first flow openings 211, and the third flow openings 213 are disposed radially outwardly of the second flow openings 212.

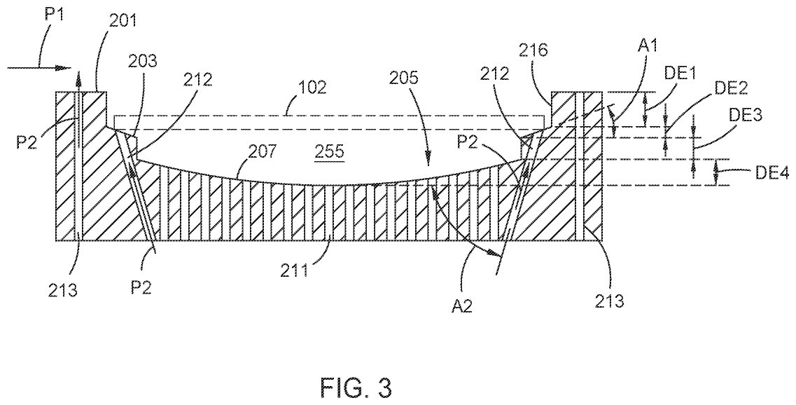

FIG. 3 is a schematic side cross-sectional view, along Section 3-3, of the substrate support 200 shown in FIG. 2, according to one or more embodiments.

The ledge 203 of the substrate support 200 is oriented at a first angle A1 relative to a plane of a lower end of the ledge 203. In one or more embodiments, the ledge 203 has an average surfaces roughness (Ra) that is less than 5 microns, such as within a range of 3.0 microns to 3.5 microns. In one or more embodiments, the first angle A1 is an oblique angle. In one or more embodiments, the first angle A1 is within a range of 0 degrees to 5 degrees, such as about 3 degrees. The ledge is configured to support the substrate 102 (shown in ghost in FIG. 3) during epitaxial deposition processing that deposits film on the substrate. In one or more embodiments, a backside of the substrate 102 covers upper ends of the second flow openings 212 when the substrate 102 is supported by the ledge 203. In one or more embodiments, the film deposited on the substrate 102 includes silicon and/or germanium. In one or more embodiments, the film includes silicon carbide. In one or more embodiments, the substrate support 200 is formed of one or more metals (such as aluminum and/or stainless steel) and/or one or more ceramics. In one or more embodiments, the substrate support 200 is formed of silicon carbide and/or graphite coated with silicon carbide. The plurality of second flow openings 212 are oriented at a second angle A2 relative to a plane of a lower end of the pocket surface 207. In one or more embodiments, the second angle A2 is an oblique angle. The second angle A2 is 20 degrees or higher. In one or more embodiments, the second angle A2 is within a range of 20 degrees to 90 degrees, such as within a range of 50 degrees to 60 degrees. In one or more embodiments, the second angle A2 is about 55 degrees. In one or more embodiments, the substrate support 200 includes a susceptor.

An upper end of the ledge 203 is disposed at a first depth DE1 relative to the first outer surface 201, and the lower end of the ledge 203 is disposed at a second depth DE2 relative to the first depth DE1. An upper end of the pocket surface 207 is disposed at a third depth DE3 relative to the lower end of the ledge 203, and the lower end of the pocket surface 207 is disposed at a fourth depth DE4 relative to the upper end of the pocket surface 207. In one or more embodiments, the third depth DE3 is a first depth ratio of the second depth D2, and the first depth ratio is within a range of 0.09 to 0.4. In one or more embodiments, the fourth depth DE4 is about equal (such as within a difference of 5% or less) to the third depth DE3. In one or more embodiments, the first depth DE1 is within a range of 0.5 mm to 1.0 mm, such as 0.6 mm to 1.0 mm. In one or more embodiments, the second depth DE2 is within a range of 0.2 mm to 0.44 mm, such as 0.2 mm to 0.4 mm, for example 0.25 mm to 0.35 mm.

In one or more embodiments, the third depth DE3 is 0.1 mm or less, such as within a range of 0.03 mm to 0.1 mm. In one or more embodiments, the fourth depth DE4 is 0.1 mm or less, such as within a range of 0.03 mm to 0.1 mm.

Gas (such as the one or more purge gases P2) can flow from below the substrate support 106 and through the third flow openings 213 and the second flow openings 212. The gas can be supplied to a volume 255 or exhausted from the volume 255 through the first flow openings 211.

The substrate support 200 facilitates benefits of reduced unwanted deposition, such as on an inner wall 216, the ledge 203, and/or the pocket surface 207 of the substrate support 200, and/or on a backside of the substrate 102 being processed. As an example, the first angle A1, the second A2 of the second flow openings 312, and the third flow openings 313 facilitate gas flow stability of the one or more purge gases P1 and the one or more process gases P1, reduced or eliminated chances of the substrate 102 fusing to the substrate support 200, and reduced or eliminated chances of breakage of the substrate 102. The first angle A1, the second A2 of the second flow openings 312, and the third flow openings 313 also facilitate reduced or eliminated contamination of the substrate support 200 and/or the substrate 102.

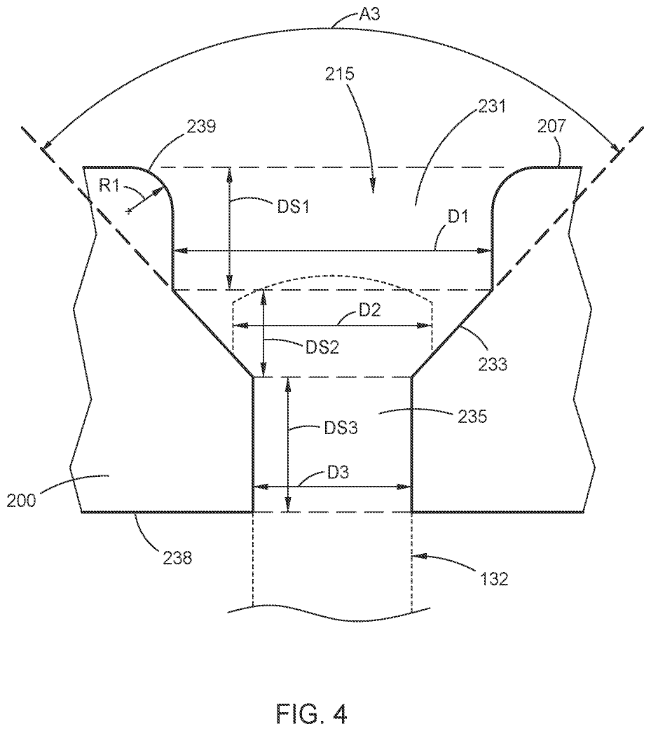

FIG. 4 is a schematic side cross-sectional view, along Section 4-4, of the substrate support shown in FIG. 2, according to one or more embodiments.

At least one of the one or more lift pin openings 215 (such as one, two, or all three of the lift pin openings 215 show in FIG. 2) of the substrate support 200 includes an opening section 231 having a diameter D1. In one or more embodiments, the diameter D1 is within a range of 5.3 mm to 5.8 mm, for example 5.5 mm to 5.8 mm, such as about 5.55 mm or about 5.75 mm. The at least one of the one or more lift pin openings 215 includes a ledge 233 recessed relative to the pocket surface 207 by a first distance DS1 and extending (e.g., downwardly and into the substrate support 200) by a second distance DS2. A sum of the first distance DS1 and the second distance DS2 added together is lesser than the diameter D1. The at least one of the one or more lift pin openings 215 includes a hole section 235 extending relative to the ledge 233. The hole section 235 extends by a third distance DS3 to a second outer surface 238 (e.g., a lower surface) of the substrate support 200. In one or more embodiments, the ledge 233 defines a third angle A3 that is at least 80 degrees. In one or more embodiments, the third angle A3 is within a range of 80 degrees to 100 degrees, such as about 90 degrees.

The at least one of the one or more lift pin openings 215 includes an arcuate surface 239 along an inner edge thereof. The arcuate surface 239 has a radius 240. In one or more embodiments, the sum of the first distance DS1 and the second distance DS2 is within a range of 2.7 mm to 3.2 mm. The sum can define a pocket depth. In one or more embodiments, the sum is a first ratio of the diameter D1, and the first ratio is within a range of 0.45 to 0.65, such as 0.45 to 0.60. In one or more embodiments, the radius 240 is within a range of 0.1 mm to 0.5 mm, such as within a range of 0.2 mm to 0.3 mm. In one or more embodiments, the radius 240 is about 0.25 mm. In one or more embodiments, the radius 240 is a second ratio of the diameter D1, and the second ratio is 0.1 or less, such as within a range of 0.015 to 0.1.

A lift pin 132 is sized and shaped for disposition in the at least one of the one or more lift pin openings 215. A head 133 of the lift pin 132 has a second diameter D2. In one or more embodiments, the second diameter D2 is a third ratio of the diameter D1, and the third ratio is 0.70 or less. In one or more embodiments, the lift pins are formed of glassy carbon. In one or more embodiments, the second diameter D2 is within a range of 3.0 mm to 3.6 mm.

The sum of the first distance DS1 and the second distance DS2 is a fourth ratio of the second diameter D2. In one or more embodiments, the fourth ratio is within a range of 0.85 to 0.95, such as within a range of 0.87 to 0.93. The first diameter D1 is a fifth ratio of the second diameter D2. In one or more embodiments, the fifth ratio is within a range of 1.45 to 1.95, for example within a range of 1.55 to 1.95, such as within a range of 1.59 to 1.85. The radius 240 is a sixth ratio of the second diameter D2. In one or more embodiments, the sixth ratio is within a range of 0.065 to 0.085, such as within a range of 0.069 to 0.084. The hole section 235 has a third diameter D3. In one or more embodiments, the third diameter D3 is a seventh ratio of the first diameter D1, and the seventh ratio is at least 1.3, such as 1.5 or higher, for example 1.6 or higher. In one or more embodiments, the third diameter D3 is within a range of 3.6 mm to 4.0 mm, such as about 3.8 mm.

The lift pin openings 215 facilitate benefits of reduced or eliminated erosion of the substrate support 200 (such as reduced or eliminated erosion of a silicon carbide of the substrate support 200) and/or reduced or eliminated contamination (such as a reduced or eliminated shadowing effect) of the lift pins 132, the substrate 102 and/or the substrate support 200. The lift pin openings 215 also facilitate enhanced thermal uniformity and deposition uniformity of the substrate support 200 and the substrate 102 being processed.

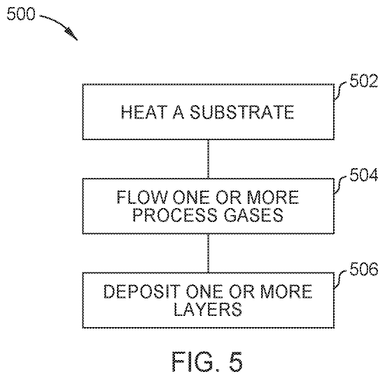

FIG. 5 is a schematic block diagram view of a method 500 of substrate processing for semiconductor manufacturing, according to one or more embodiments.

Operation 502 of the method 500 includes heating a substrate positioned on a substrate support in a processing volume of a processing chamber. In one or more embodiments, the substrate is heated to a target temperature. In one or more embodiments, the target temperature is 800 degrees Celsius or higher, such as 1,000 degrees Celsius or higher. Other target temperatures are contemplated.

Operation 504 includes flowing one or more process gases over the substrate.

Operation 506 includes depositing one or more layers on the substrate.

Benefits of the present disclosure include reduced or eliminated contamination (e.g., of substrates and/or chamber components); more targeted deposition (e.g., reduced or eliminated deposition on chamber components and/or substrate backsides); enhanced thermal uniformity and deposition uniformity; reduced or eliminated component wear; increased lifespans of components (such as substrate supports and lift pins); increased throughput; increased numbers of processed substrates between cleaning cycles; reduced cleaning; reduced or eliminated substrate fusing; reduced or eliminated substrate breakage; and reduced machine downtime. Such benefits can be facilitated, for example, for processing parameters having a higher intensity (e.g., processing temperatures of 800 degrees Celsius or higher, such as 1,000 degrees Celsius or higher).

It is contemplated that one or more aspects disclosed herein may be combined. As an example, one or more aspects, features, components, operations and/or properties of the processing chamber 100; the controller 190; the substrate support 106, the substrate support 200, the flow openings 211-213, the lift pin openings 215, and/or the method 500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated.

What is claimed is:

1. A substrate support applicable for semiconductor manufacturing, comprising:
a first outer surface;
a ledge disposed inwardly of the first outer surface and recessed relative to the first outer surface;
a pocket defining a pocket surface that is disposed inwardly of the ledge and recessed relative to the ledge;
a plurality of first flow openings extending into the pocket surface;
a plurality of second flow openings extending into the ledge; and
a plurality of third flow openings extending into the first outer surface.

2. The substrate support of claim 1, further comprising a plurality of lift pin openings extending into the pocket surface.

3. The substrate support of claim 1, wherein the ledge is oriented at an angle relative to a plane of a lower end of the ledge, and the angle is within a range of 0 degrees to 5 degrees.

4. The substrate support of claim 3, wherein the plurality of second flow openings are oriented at an oblique angle relative to a plane of a lower end of the pocket.

5. The substrate support of claim 4, wherein the oblique angle is 20 degrees or higher.

6. The substrate support of claim 5, wherein the oblique angle is within a range of 50 degrees to 60 degrees.

7. The substrate support of claim 1, wherein the second flow openings and the third flow openings are respectively disposed along a circular row.

8. The substrate support of claim 7, wherein the first flow openings are disposed along a plurality of rows.

9. A substrate support applicable for semiconductor manufacturing, comprising:
a first outer surface;
a pocket defining a pocket surface that is disposed inwardly of the first outer surface and recessed relative to the first outer surface; and
one or more lift pin openings, at least one of the one or more lift pin openings comprising:
an opening section having a diameter,
a ledge recessed relative to the pocket surface by a first distance and extending by a second distance, a sum of the first distance and the second distance lesser than the diameter, and
a hole section extending relative to the ledge.

10. The substrate support of claim 9, wherein the sum is a ratio of the diameter, and the ratio is within a range of 0.45 to 0.65.

11. The substrate support of claim 9, wherein the sum is within a range of 2.7 mm to 3.2 mm.

12. The substrate support of claim 9, wherein the diameter is within a range of 5.3 mm to 5.8 mm.

13. The substrate support of claim 9, wherein the at least one of the one or more lift pin openings comprises an arcuate surface along an inner edge thereof.

14. The substrate support of claim 13, wherein the arcuate surface has a radius, the radius is a ratio of the diameter, and the ratio is 0.1 or less.

15. The substrate support of claim 9, further comprising a lift pin sized and shaped for disposition in the at least one of the one or more lift pin openings.

16. The substrate support of claim 15, wherein a head of the lift pin has a second diameter that is a ratio of the diameter, and the ratio is 0.70 or less.

17. The substrate support of claim 15, wherein a head of the lift pin has a second diameter, the diameter is a ratio of the second diameter, and the ratio is within a range of 1.45 to 1.95.

18. The substrate support of claim 15, wherein a head of the lift pin has a second diameter, the sum is a ratio of the second diameter, and the ratio is within a range of 0.85 to 0.95.

19. A processing chamber applicable for semiconductor manufacturing, comprising:
one or more sidewalls;
a window at least partially defining a processing volume;
one or more heat sources operable to heat the processing volume; and
a substrate support disposed in the processing volume, the substrate support comprising:
a first outer surface,
a ledge disposed inwardly of the first outer surface and recessed relative to the first outer surface,
a pocket defining a pocket surface that is disposed inwardly of the ledge and recessed relative to the ledge,
a plurality of second flow openings extending into the ledge,
a plurality of third flow openings extending into the first outer surface, and
one or more lift pin openings, at least one of the one or more lift pin openings comprising:
an opening section having a diameter,
a ledge recessed relative to the pocket surface by a first distance and extending by a second distance, a sum of the first distance and the second distance lesser than the diameter.

20. The substrate support of claim 19, further comprising a lift pin sized and shaped for disposition in the at least one of the one or more lift pin openings, wherein the lift pin has a second diameter, at least one of the one or more lift pin openings comprises an arcuate surface along an inner edge thereof, the arcuate surface has a radius, the radius is a ratio of the second diameter, and the ratio is within a range of 0.065 to 0.085.
